(19) United States
(12) Patent Application Publication
(10) Pub. No.: US 2024/0268137 A1
(43) Pub. Date: Aug. 8, 2024

(54) LIGHT-EMITTING ELEMENT AND LIGHT-EMITTING DEVICE

(71) Applicant: SHARP KABUSHIKI KAISHA, Sakai City, Osaka (JP)

(72) Inventors: YUSUKE SAKAKIBARA, Sakai City, Osaka (JP); Masaki YAMAMOTO, Sakai City, Osaka (JP)

(21) Appl. No.: 18/566,453

(22) PCT Filed: Jul. 7, 2021
(86) PCT No.: PCT/JP2021/025539

§ 371 Date: Dec. 1, 2023

(51) Int. Cl. H10K 50/115; H10K 50/16; H10K 102/00

(52) U.S. Cl. CPC H10K 50/115; H10K 50/166; H10K 2102/351

(57) ABSTRACT

A light-emitting element includes an anode electrode, an EML containing a QD dispersed in a non-polar solvent, a first ETL containing an MOP dispersed in a polar solvent, the first ETL being adjacent to the EML, a second ETL-containing an MOP dispersed in a non-polar solvent, the second ETL being adjacent to the first ETL, and a cathode electrode, which are layered in this order from a lower layer side.

### TECHNICAL FIELD

The disclosure relates to a light-emitting element including an electron transport layer containing metal oxide nanoparticles, and a light-emitting device including the light-emitting element.

### BACKGROUND ART

Light-emitting elements using metal oxide nanoparticles as electron transport materials have been proposed in recent years. For example, PTL 1 discloses a light-emitting element in which an electron transport layer using metal oxide nanoparticles is provided on a quantum dot light-emitting layer.

### CITATION LIST

### Patent Literature

PTL 1: JP 2010-114079 A

### Non Patent Literature

NPL 1: ACS Photonics, 2016, 3, 215-222, Size Tunable ZnO Nanoparticles to Enhance Electron Injection in Solution Processed QLEDs
NPL 2: ACS Appl. Mater. Interfaces 2010, 2, 6, 1769-1773, Sol-Gel Growth of Hexagonal Faceted ZnO Prism Quantum Dots with Polar Surfaces for Enhanced Photocatalytic Activity Summary

### Technical Problem

However, when the metal oxide nanoparticles are formed into a thin film, it is difficult to maintain a band gap in a solution state. In order to improve electron transport efficiency from the electron transport layer to the quantum dot light-emitting layer, metal oxide nanoparticles having a large band gap are required.

NPL 1 discloses that the smaller a particle diameter of the metal oxide nanoparticles is made, the larger the band gap is.

However, when the particle diameter of the metal oxide nanoparticles is reduced, the metal oxide nanoparticles become unstable and easily aggregate in a solvent. Thus, in order to obtain a light-emitting element having high electron transport efficiency and excellent light-emission characteristics, it is necessary to select ligands capable of obtaining stable metal oxide nanoparticles and dispersing metal oxide nanoparticles having a small particle diameter in a solvent.

NPL 2 describes oleic acid as the ligands for the metal oxide nanoparticles.

However, metal oxide nanoparticles coordinated with ligands having long chains such as oleic acid are dispersed in a non-polar solvent. Quantum dots used in the quantum dot light-emitting layer in the related art are hardly dispersed in a polar solvent and are easily dispersed in a non-polar solvent (apolar solvent) in many cases. Thus, an electron transport layer containing such metal oxide nanoparticles cannot be formed on the quantum dot light-emitting layer by a coating method.

An aspect of the disclosure has been contrived in consideration of the above-mentioned problem, and an object thereof is to provide a light-emitting element having high electron transport efficiency and having excellent light-emission characteristics, compared with those of known light-emitting elements.

### Solution to Problem

In order to solve the above-mentioned problem, a light-emitting element according to an aspect of the disclosure includes an anode electrode, a light-emitting layer including a quantum dot dispersed in a non-polar solvent, a first electron transport layer including first metal oxide nanoparticles dispersed in a polar solvent, the first electron transport layer being adjacent to the light-emitting layer, a second electron transport layer including second metal oxide nanoparticles dispersed in a non-polar solvent, the second electron transport layer being adjacent to the first electron transport layer, and a cathode electrode, wherein the anode electrode, the light-emitting layer, the first electron transport layer, the second electron transport layer, and the cathode electrode are layered in this order from a lower layer side.

In order to solve the problem described above, a light-emitting device according to an aspect of the disclosure includes the light-emitting element according to an aspect of the disclosure.

### Advantageous Effects of Disclosure

According to an aspect of the disclosure, it is possible to provide a light-emitting element having high electron transport efficiency and excellent light-emission characteristics, compared with known light-emitting elements.

### BRIEF DESCRIPTION OF DRAWINGS

FIG. 1 is a cross-sectional view illustrating an example of a schematic configuration of main portions of a display device according to a first embodiment.

FIG. 2 is a schematic view illustrating an example of a light-emitting element according to the first embodiment.

FIG. 3 is a schematic view illustrating another example of the light-emitting element according to the first embodiment.

FIG. 4 is a flowchart illustrating an example of a manufacturing method for the light-emitting element according to the first embodiment.

FIG. 5 is a flowchart illustrating an example of a method for preparing a colloidal dispersion to be used as a first material dispersion or a second material dispersion.

FIG. 6 is a graph showing a relationship between (αhv)² and hv in a solution state and a thin film state of zinc oxide nanoparticles not coordinated with a ligand.

FIG. 7 is a graph showing a relationship between (αhv)² and hv in a solution state and a thin film state of zinc oxide nanoparticles coordinated with oleic acid as a ligand having a long chain.

FIG. 8 is a cross-sectional view illustrating an example of a schematic configuration of main portions when a bank having good coatability with respect to polar solvents is used.

FIG. 9 is a cross-sectional view illustrating an example of a schematic configuration of main portions when a bank having good coatability with respect to non-polar solvents is used.

### DESCRIPTION OF EMBODIMENTS

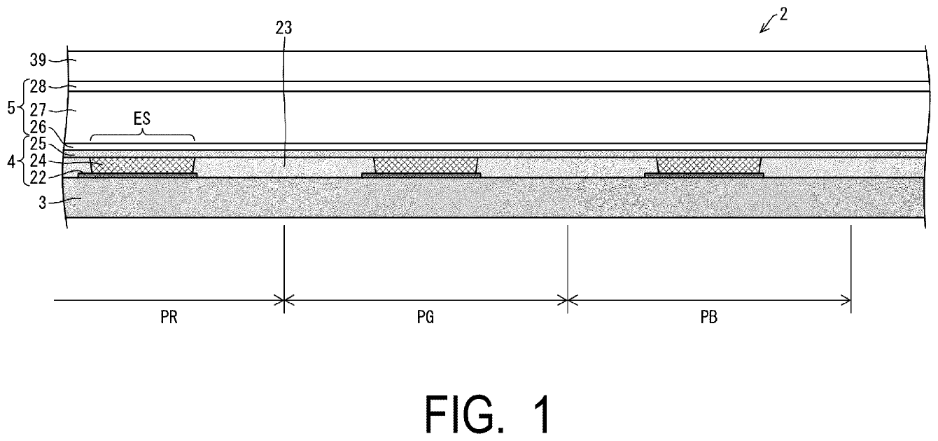

An embodiment of the disclosure will be described as follows with reference to FIG. 1 to FIG. 9. Note that, in the following, description of “from A to B” for two numbers A and B means “being equal to or greater than A and equal to or less than B”, unless otherwise specified.

In the following, description will be made using, as an example, a case in which a light-emitting device according to the present embodiment is a display device.

Display Device FIG. 1 is a cross-sectional view illustrating an example of a schematic configuration of main portions of a display device 2 according to the present embodiment.

The display device 2 includes a plurality of pixels. A light-emitting element ES is provided in each pixel. The display device 2 includes, as a substrate 3, an array substrate formed with a drive element layer, and has a configuration in which a light-emitting element layer 4 including a plurality of light-emitting elements ES of different light emission wavelengths, a sealing layer 5, and a function film 39 are layered in this order on the substrate 3. Note that in the present embodiment, a direction from the light-emitting element ES of the display device 2 to the substrate 3 is referred to as a “downward direction”, and a direction from the substrate 3 of the display device 2 to the light-emitting element ES is referred to as an “upward direction”. In addition, in the present embodiment, a “lower layer” means a layer that is formed in a process prior to that of a layer to be compared, and an “upper layer” means a layer that is formed in a process after that of a layer to be compared.

The display device 2 illustrated in FIG. 1 includes, as pixels, a red pixel PR that emits red light, a green pixel PG that emits green light, and a blue pixel PB that emits blue light. A bank 23 with insulating properties for partitioning adjacent pixels to each other is provided as a pixel separation film between the pixels.

The display device 2 includes a red light-emitting element that emits red light, a green light-emitting element that emits green light, and a blue light-emitting element that emits blue light as the plurality of light-emitting elements ES having different light emission wavelengths. In the red pixel PR, the red light-emitting element is provided as the light-emitting element ES. In the green pixel PG, the green light-emitting element is provided as the light-emitting element ES. In the blue pixel PB, the blue light-emitting element is provided as the light-emitting element ES.

The light-emitting element layer 4 includes the plurality of light-emitting elements ES provided in respective pixels, and has a structure in which each layer of the light-emitting elements ES is layered over the substrate 3.

The substrate 3 functions as a support body for forming each layer of the light-emitting elements ES. The substrate 3 is the array substrate, and a thin film transistor (TFT) layer, for example, is formed at the substrate 3 as the drive element layer. The TFT layer is provided with a pixel circuit including a drive element such as a TFT controlling the light-emitting elements ES.

The light-emitting element layer 4 includes a plurality of anode electrodes 22, a cathode electrode 25, a function layer 24 provided between the anode electrodes 22 and the cathode electrode 25, and the bank 23 having insulating properties and covering an edge of each of the anode electrodes 22. The anode electrode 22 is a lower layer electrode (island-shaped lower layer electrode, so-called “pixel electrode”) provided in an island shape for each light-emitting element ES (in other words, for each pixel) on the substrate 3. The cathode electrode 25 is an upper layer electrode (common upper layer electrode) provided in common to all the light-emitting elements ES (in other words, all the pixels) in an upper layer than the lower layer electrode with the function layer 24 and the bank 23 interposed therebetween.

Note that, in the present embodiment, the layers between the anode electrodes 22 and the cathode electrode 25 are collectively referred to as the function layer 24. The function layer 24 includes at least a light-emitting layer, a first electron transport layer adjacent to the light-emitting layer, and a second electron transport layer that is adjacent to the first electron transport layer and that is provided between the first electron transport layer and the cathode electrode 25. Among the function layers 24, examples of a function layer other than the light-emitting layer, the first electron transport layer, and the second electron transport layer include a hole transport layer. Hereinafter, the light-emitting layer will be denoted as the “EML”. Also, the electron transport layer will be denoted as the “ETL”. Accordingly, hereinafter, the first electron transport layer is denoted as the “first ETL”, and the second electron transport layer is denoted as the “second ETL”. Furthermore, the hole transport layer will be denoted as the “HTL”.

The bank 23 is used as an edge cover that covers an edge of the patterned lower layer electrode and also functions as a pixel separation film. The bank 23 is formed by applying an organic material such as polyimide or acrylic resin, and then, patterning the applied organic material by photolithography, for example.

In the present embodiment, as an example, as illustrated in FIG. 1, the anode electrode 22 and the function layer 24 are separated (patterned) in an island shape for each pixel by the bank 23. Thus, in the light-emitting element layer 4, the light-emitting element ES including the anode electrode 22, the function layer 24, and the cathode electrode 25 is provided corresponding to each pixel. Each anode electrode 22 serving as the lower layer electrode is electrically connected to the TFT of the substrate 3. Note that a configuration of the light-emitting element ES will be described in more detail below.

The light-emitting element layer 4 is covered by the sealing layer 5. The sealing layer 5 has transparency and includes, for example, a first inorganic sealing film 26, an organic sealing film 27, and a second inorganic sealing film 28 in the order from the lower layer side (that is, the light-emitting element layer 4 side). However, the sealing layer 5 is not limited thereto, and the sealing layer 5 may be formed of a single layer of an inorganic sealing film or a layered body of five or more layers of an organic sealing film and an inorganic sealing film. Also, the sealing layer 5 may be a sealing glass, for example. The light-emitting element ES is sealed by the sealing layer 5, and thus water, oxygen, or the like can be prevented from permeating into the light-emitting element ES.

Each of the first inorganic sealing film 26 and the second inorganic sealing film 28 can be formed of, for example, a silicon oxide film, a silicon nitride film, or a silicon oxynitride film formed by chemical vapor deposition (CVD) or of a layered film of these films. The organic sealing film 27 is a transparent organic film thicker than the first inorganic sealing film 26 and the second inorganic sealing film 28, and can be formed of, for example, coatable photosensitive resin such as polyimide resin or acrylic resin.

Note that, as illustrated in FIG. 1, the display device 2 may include, on the sealing layer 5, the function film 39 having at least one of an optical compensation function, a touch sensor function, and a protection function, for example.

### Light-Emitting Element

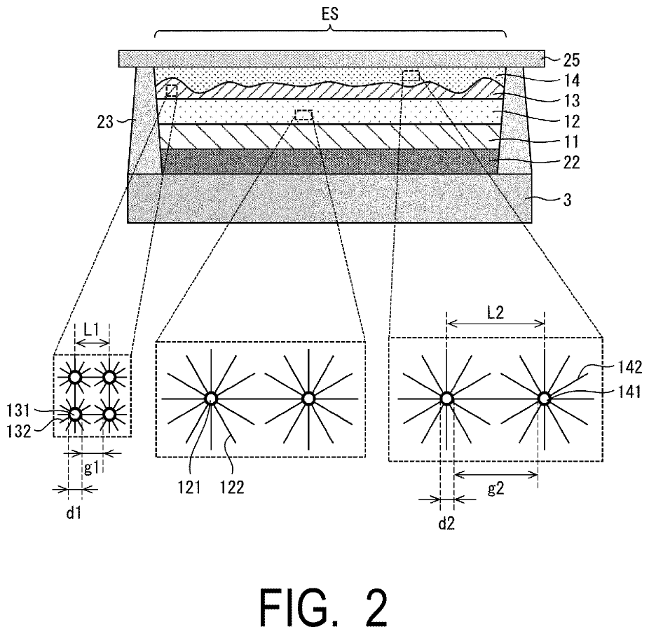

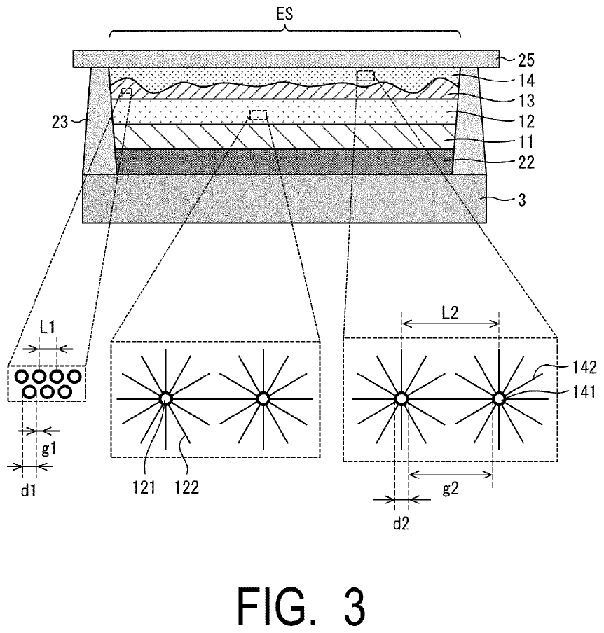

FIG. 2 is a schematic view illustrating an example of the light-emitting element ES according to the present embodiment. FIG. 3 is a schematic view illustrating another example of the light-emitting element ES according to the present embodiment.

As one example, the light-emitting element ES illustrated in FIG. 2 and FIG. 3 has a configuration in which the anode electrode 22, an HTL 11, the EML 12, a first ETL 13, a second ETL 14, and the cathode electrode 25 are adjacent to each other and layered in this order from the lower layer side.

Note that in the display device 2, the substrate 3 functions as a support body for forming each layer of the light-emitting element ES. In this way, each layer of the light-emitting element ES is formed on the substrate as the support body. Thus, when the light-emitting element ES is manufactured as an independent product, the light-emitting element ES including the substrate as the support body may be referred to as a light-emitting element.

The anode electrode 22 and the cathode electrode 25 are connected to a power supply (not illustrated) (for example, a DC power supply), and thus, a voltage is applied therebetween.

The anode electrode 22 is an electrode that supplies positive holes (holes) to the EML 12 when a voltage is applied thereto. The cathode electrode 25 is an electrode that supplies electrons to the EML 12 when a voltage is applied thereto.

At least one of the anode electrode 22 and the cathode electrode 25 is made of a light-transmissive material. Note that the anode electrode 22 or the cathode electrode 25 may be formed of a light-reflective material. The light-emitting element ES can extract light from the side of the electrode made of a light-transmissive material.

The materials of the anode electrode 22 and the cathode electrode 25 are not particularly limited, and the same materials as or similar materials to those used as materials of anode electrodes and cathode electrodes of light-emitting elements in the related art can be used.

The anode electrode 22 is made of, for example, a material having a relatively large work function. Examples of the materials include tin-doped indium oxide (ITO), zinc-doped indium oxide (IZO), aluminum-doped zinc oxide (AZO), gallium-doped zinc oxide (GZO), and antimony-doped tin oxide (ATO). A single type of these materials may be used alone, or two or more types may be mixed and used, as appropriate.

The cathode electrode 25 is made of, for example, a material having a relatively small work function. Examples of the material include Al, silver (Ag), Ba, ytterbium (Yb), calcium (Ca), lithium (Li)—Al alloys, Mg—Al alloys, Mg—Ag alloys, Mg-indium (In) alloys, and Al-aluminum oxide (Al₂O₃) alloys.

The light-emitting element ES is an electroluminescent element (photoelectric conversion element), and emits light when a voltage is applied to the EML 12. The EML 12 includes a light-emitting material and emits light due to recombination between positive holes transported from the anode electrode 22 and electrons transported from the cathode electrode 25. The light-emitting element ES according to the present embodiment is a quantum dot light emitting diode (QLED), and as illustrated in FIG. 2, the EML 12 contains nano-sized quantum dots (hereinafter, referred to as “QDs”) 121 corresponding to a luminescent color as a light-emitting material. The red light-emitting element includes, as the EML 12, a red EML containing a red QD that emits red light as the QD 121. The green light-emitting element includes, as the EML 12, a green EML containing a green QD that emits green light as the QD 121. The blue light-emitting element includes, as the EML 12, a blue EML containing a blue QD that emits blue light as the QD 121. The same light-emitting elements ES (the same pixels) have the same type of QDs 121.

As described above, the EML 12 according to the present embodiment is a QD light-emitting layer containing the QDs 121. With the light-emitting element ES according to the present embodiment, positive holes and electrons recombine inside the EML 12 in response to a drive current between the anode electrode 22 and the cathode electrode 25, which generates excitons to emit light in the process of transition from a conduction band level to a valence band level of the QDs 121.

The QD 121 is a semiconductor nanoparticle (semiconductor nanocrystal) having a crystal structure, and the semiconductor nanoparticle is called a nanocrystal. As illustrated in FIG. 2, a large number of ligands 122 are preferably coordinated (adsorbed) on the surface of the QD 121. The ligand 122 is a surface modifier that coordinates the surface of the QD to modify the surface of the QD.

With the ligands 122 coordinated to the surfaces of the QDs 121, mutual aggregation of the QDs 121 when the QDs 121 are dispersed in a solvent can be suppressed. Thus, coordinating the ligands 122 on the surfaces of the QDs 121 can allow intended optical characteristics to be easily exhibited. Note that in the disclosure, dispersion means dispersing a solute in a solvent into a colloidal state.

For an EML formed by using a QD dispersion in which QDs are dispersed in a solvent in such a way, QDs obtained by modifying QDs as a light-emitting material with ligands are generally used, and the EML contains the ligands coordinated to the QDs as ligands.

In the present embodiment, as will be described later, a QD dispersion obtained by dispersing the QDs 121 in a non-polar solvent is used for manufacturing the EML 12. Thus, as described above, the surface of the QD 121 is preferably modified with the ligand 122. For this reason, the EML 12 preferably contains the QD 121 and the ligand 122. Note that as described above, the fact that the surface of the QD 121 is modified (surface-modified) with the ligand 122 means that the ligand 122 is coordinated to the surface of the QD 121.

As described above, in the present embodiment, the non-polar solvent is used as a solvent for dispersing the QDs 121. Thus, in the present embodiment, the QDs 121 that are dispersed in the non-polar solvent are used. The QDs 121 may be QDs that are dispersed in the non-polar solvent without ligands. In addition, the QDs 121 may be QDs that are dispersed in the non-polar solvent in a state where the ligands 122 are coordinated, and in this case, may be QDs that become dispersible in the non-polar solvent when the ligands 122 are coordinated. Note that as described above, many of QDs used in EMLs in the related art are hardly dispersed in a polar solvent and are easily dispersed in a non-polar solvent (apolar solvent).

The QDs 121 may contain, for example, a semiconductor material constituted by an element of at least one type selected from the group consisting of cadmium (Cd), sulfur (S), tellurium (Te), selenium (Se), zinc (Zn), indium (In), nitrogen (N), phosphorus (P), arsenic (As), antimony (Sb), aluminum (Al), gallium (Ga), lead (Pb), silicon (Si), germanium (Ge), and magnesium (Mg).

Further, the QD 121 may be a core type constituted by only a core, a core-shell type including a core and a shell, or a core-multi-shell type. Further, the QD 121 may be a two-component core type, a three-component core type, or a four-component core type.

Further, the QD 121 may contain a doped semiconductor nanoparticle, or may have a compositionally graded structure. Light emission wavelengths of the QDs 121 can be changed in various ways depending on, for example, a particle diameter and composition thereof.

Examples of the ligand 122 include ligands that are generally used for QDs in the related art. Examples of the ligand 122 include oleic acid, dodecanoic acid, dodecanethiol, dodecylamine, trioctylphosphine, and trioctylphosphine oxide.

The HTL 11 is a layer that contains a hole transport material and that transports positive holes supplied from the anode electrode 22 to the EML 12. The hole transport material may be an organic material or may be an inorganic material.

When the hole transport material is an organic material, examples of the organic material include conductive polymer materials such as poly[(9,9-dioctylfluorenyl-2,7-diyl)-co-(4,4′-(N-(4-sec-butylphenyl)diphenylamine))](TFB), poly(3,4-ethylenedioxythiophene)-poly(styrenesulfonate) (PEDOT-PSS), and poly(N-vinylcarbazole) (PVK). Further, when the hole transport material is an inorganic material, examples of the inorganic material include p-type semiconductors such as metal oxide, group II-VI compound semiconductors, group III-V compound semiconductors, group IV-IV compound semiconductors, amorphous semiconductors, and thiocyanic acid compounds. A single type of these hole transport materials may be used alone, or two or more types may be mixed and used, as appropriate.

The ETL is a layer that contains an electron transport material and that transports electrons supplied from the cathode electrode 25 to the EML 12. In the present embodiment, the second ETL 14 transports the electrons supplied from the cathode electrode 25 to the first ETL 13, and the first ETL 13 transports the electrons transported from the second ETL 14 to the EML 12. As described above, the first ETL 13 is provided adjacent to the EML 12, and the second ETL 14 is provided adjacent to the first ETL 13.

Each of the first ETL 13 and the second ETL 14 contains metal oxide nanoparticles (hereinafter, referred to as “MOPs”) as the electron transport material. Note that the first ETL 13 contains MOPs 131 (first metal oxide nanoparticles) that are dispersed in a polar solvent as the electron transport material. On the other hand, the second ETL 14 contains MOPs 141 (second metal oxide nanoparticles) that are dispersed in a non-polar solvent as an electron transport material.

MOPs are easily dispersed in a polar solvent and hardly dispersed in a non-polar solvent unless a special treatment such as surface modification with ligands (ligand addition) is performed. For this reason, the MOPs 131 that are dispersed in the polar solvent may be MOPs 131 surface-modified with ligands 132 (first ligands) as illustrated in FIG. 2, or may be simple MOPs 131 not surface-modified with ligands as illustrated in FIG. 3. Thus, the first ETL 13 may contain the ligand 132 in addition to the MOP 131, or does not need to contain the ligand 132.

On the other hand, the MOPs 141 that are dispersed in the non-polar solvent are surface-modified with ligands 142 (second ligands) as illustrated in FIG. 2. Thus, the second ETL 14 contains the MOP 141 and the ligand 142.

Each of the ligand 132 and the ligand 142 is a surface modifier that coordinates to the surface of the MOP to modify the surface of the MOP. In the present embodiment, the fact that the surface of the MOP is modified with a ligand (surface modification) means that the ligand is coordinated to the surface of the MOP.

Nanoparticles of n-type metal oxide having electrons as charge carriers are used for the MOP 131 and the MOP 141. Examples of such metal oxide include zinc oxide (ZnO), magnesium zinc oxide (MgZnO), titanium oxide (TiO₂), indium oxide (In₂O₃), tin oxide (SnO, SnO₂), nickel oxide (NiO), zirconium oxide (ZrO₂), tungsten oxide (WOₓ:x=1 to 6), cerium oxide (CeO₂), and tantalum oxide (Ta₂O₅), and mixed crystals thereof. A single type of nanoparticles of these metal oxides may be used alone, or two or more types may be mixed and used, as appropriate. In addition, the metal oxide nanoparticles to be used for the MOP 131 and the metal oxide nanoparticles to be used for the MOP 141 may be the same as or different from each other, but may each preferably contain zinc (Zn). The metal oxide nanoparticles containing zinc can have high electron transportability and high luminous efficiency.

The ligand 132 is a ligand including from 1 to 7 carbons per molecule. On the other hand, the ligand 142 is a ligand including 8 or more carbons per molecule, and preferably a ligand including from 8 to 30 carbons per molecule.

The ligand is generally constituted by a coordinating functional group (adsorbing group) coordinated (adsorbed) to the surface of a nanoparticle and a carbon chain such as an alkyl chain bonded to the coordinating functional group.

The coordinating functional group is not particularly limited, and it is sufficient that the coordinating functional group is a functional group that can coordinate to a nanoparticle to be coordinated. Examples thereof include at least one type of functional group selected from the group consisting of, for example, a thiol (—SH) group, an amino (—NR₂) group, a carboxyl (—C(═O)OH) group, a phosphonic (—P(═O)(OR)₂) group, a phosphine (—PR₂) group, and a phosphine oxide (—P(═O)R₂) group. The R groups each independently represent a hydrogen atom or any organic group such as an alkyl group or an aryl group. The amino group may be any of primary, secondary, and tertiary amino groups, but among them, a primary amino (—NH₂) group is particularly preferable. The phosphonic group, the phosphine group, and the phosphine oxide group may also be any of primary, secondary, and tertiary groups, but the phosphonic group, the phosphine group, and the phosphine oxide group are particularly preferably a tertiary phosphonic (—P(═O)(OR)₂) group, a tertiary phosphine (—PR₂) group, and a tertiary phosphine oxide (—P(═O)R₂) group, respectively, with the R group being an alkyl group.

A ligand tends to have a longer molecular length and a lower polarity as the number of carbons of the carbon chain bonded to the coordinating functional group increases. Then, the ligand to be coordinated to the MOP is preferably a monodentate ligand including only one coordinating functional group described above, and there are few instances where the number of carbons per molecule of the ligand is different from the number of carbons of the longest carbon chain bonded to the coordinating functional group.

Note that here, the longest carbon chain bonded to the coordinating functional group refers to a carbon chain having the largest number of carbon atoms contained in a carbon chain connecting the coordinating functional group to a terminal group at the shortest distance (that is, a structure in which carbon atoms are connected to each other without branching).

Thus, the ligand tends to have a longer molecular length and a smaller polarity as the number of carbons per molecule increases, and MOPs each of which is coordinated with a ligand having a long chain with a large number of carbons per molecule are easily dispersed in non-polar solvents and hardly dispersed in polar solvents. On the other hand, MOPs that do not contain a ligand or MOPs each of which is coordinated with a ligand having a short chain with a small number of carbons per molecule are easily dispersed in polar solvents and are hardly dispersed in non-polar solvents.

As a result of intensive studies by the inventors of the present application, MOPs to which no ligand is coordinated or MOPs each of which is coordinated with a ligand having a short chain with 7 or less carbons per molecule (that is, including from 1 to 7 carbons per molecule) are dispersed in polar solvents. On the other hand, MOPs each of which is coordinated with a ligand having a long chain with 8 or more carbons per molecule are dispersed in non-polar solvents. However, when a ligand including more than 30 carbons per molecule is used, an effect of electrical insulation of the ligand is increased, and electron transportability may be lowered. Accordingly, as described above, the number of carbons per molecule in the ligand 142 is preferably equal to or more than 8 and equal to or less than 30.

Table 1 shows examples of a ligand with a short chain to be used as the ligand 132 and a ligand with a long chain to be used as the ligand 142, the number of carbons per molecule contained in each of these ligands, and the number of carbons in the longest carbon chain in each of these ligands.

TABLE 1

| | | | Number |
|---|---|---|---|
| | | Number of | of carbons |
| | | carbons per | in longest |
| | Ligand | molecule | carbon chain |
| Short chain (first | Ethanolamine | 2 | 2 |
| ligand) | Diethanolamine | 4 | 2 |
| | Triethanolamine | 6 | 2 |
| | p-toluenethiol | 7 | 5 |
| Long chain (second | Oleic acid | 18 | 18 |
| ligand) | Stearic acid | 18 | 18 |
| | Palmitic acid | 16 | 16 |
| | Octylphosphonic acid | 8 | 8 |
| | Tetradecylphosphonic | 14 | 14 |
| | acid | | |
| | Octadecylphosphonic | 18 | 18 |
| | acid | | |
| | Octylamine | 8 | 8 |
| | Dodecylamine | 12 | 12 |
| | Hexadecylamine | 16 | 16 |
| | Oleylamine | 18 | 18 |
| | Octanethiol | 8 | 8 |
| | Dodecanethiol | 12 | 12 |
| | Octadecanethiol | 18 | 18 |
| | Trioctylphosphine | 24 | 8 |

As shown in Table 1, examples of the ligand 132 include at least one type of ligand selected from the group consisting of ethanolamine, diethanolamine, triethanol amine, and p-toluenethiol.

Further, as shown in Table 1, examples of the ligand 142 include at least one type of ligand selected from the group consisting of oleic acid, stearic acid, palmitic acid, octylphosphonic acid, tetradecylphosphonic acid, octadecylphosphonic acid, octylamine, dodecylamine, hexadecylamine, oleylamine, octanethiol, dodecanethiol, octadecanethiol, and trioctylphosphine.

As shown in Table 1, there are few examples in which the number of carbons per molecule in each of the ligand with the short chain to be used as the ligand 132 and the ligand with the long chain to be used as the ligand 142 is different from the number of carbons in the longest carbon chain. In addition, even when the number of carbons per molecule is different from the number of carbons in the longest carbon chain, a ligand including 7 or less carbons per molecule has 7 or less carbons in the longest carbon chain, and a ligand including 8 or more carbons per molecule has 8 or more carbons in the longest carbon chain.

As described above, the carbon chain of the ligand 142 is longer than that of the ligand 132. Thus, as illustrated in FIG. 2 and FIG. 3, a number average value of a distance g2 between surfaces of the MOPs 141 adjacent to each other is larger than a number average value of a distance g1 between surfaces of the MOPs 131 adjacent to each other.

When a distance between surfaces of MOPs adjacent to each other is small, there is a tendency that the particle diameter is easily increased by aggregation or the like. On the other hand, when the distance between the surfaces of the MOPs adjacent to each other is increased, the MOPs are less likely to aggregate, and the particle diameter is easily maintained small. Thus, a number average particle diameter of the MOP 141 to which the ligand 142 is coordinated is smaller than a number average particle diameter of the MOP 131 to which the ligand 132 is coordinated.

Note that the distance between the surfaces of the MOPs adjacent to each other is represented by a value obtained by subtracting a number average value of the particle diameter of the MOP (number average particle diameter) from a number average value of a center-to-center distance between the MOPs adjacent to each other (average MOP center-to-center distance). The average MOP center-to-center distance can be measured by using, for example, a small angle X-ray scattering pattern by a dynamic light scattering method or a cross-sectional Transmission type Electron Microscope (TEM) image. Similarly, a number average particle diameter of nanoparticles such as MOPs or QDs can be measured by using, for example, the dynamic light scattering method or a cross-sectional TEM image. In the disclosure, the “number average particle diameter” means a design value of a particle diameter or a median value of a particle diameter measured by the dynamic light scattering method or the cross-sectional TEM image. Thus, the number average particle diameter of the nanoparticles indicates, for example, the diameter of a nanoparticle at an integrated value of 50% in particle size distribution of the particle diameters measured by, for example, the dynamic light scattering method. In addition, when the number average particle diameter of the nanoparticles is obtained by using, for example, the cross-sectional TEM image, the number average particle diameter can be obtained as follows. First, by using the outer shape of each cross section of a predetermined number of nanoparticles adjacent to each other with, for example, a TEM, the area of the cross section of each nanoparticle is obtained. Next, all of these nanoparticles are assumed to be perfect circles, and the diameter corresponding to the area of the perfect circle that is the area of the cross section of each nanoparticle is calculated. Then, the median value of the diameters of the perfect circles is obtained by calculating the average value of the calculated diameters.

In the present embodiment, the number average value (number average particle diameter) of the particle diameter d2 (diameter) of the MOP 141 is preferably equal to or less than 5 nm.

The smaller the number average particle diameter of the MOP is, the smaller the value of a conduction band minimum (CBM) of the MOP becomes due to a quantum effect (in other words, the CBM becomes shallower). On the other hand, even when the particle diameter of the MOP changes, the value of a valence band maximum (VBM) of the MOP does not change. Note that here, the value of the CBM indicates the absolute value of a difference in electron energy level between a vacuum level and the conduction band minimum (CBM). In addition, the value of the VBM indicates the absolute value of a difference in electron energy level between the vacuum level and the VBM. Thus, the smaller the number average particle diameter of the MOP becomes, the shallower the CBM becomes, and then, the smaller an electron injection barrier becomes, the larger a band gap between the CBM and the VBM of the MOP becomes. As a result, the electron transport efficiency is improved.

For example, when the MOP is zinc oxide (ZnO) and the number average particle diameter thereof is equal to or less than 5 nm, the value of the CBM of the MOP is equal to or less than 2.7 eV. A value of the CBM of a blue MOP is equal to or larger than 2.7 eV in many cases. When the value of the CBM of the MOP is equal to or smaller than the value of the CBM of the blue MOP, electrons easily move from the ETL to the blue EML. Further, the value of the CBM of a QD contained in an EML tends to decrease as the light emission wavelength of the EML decreases. Specifically, the blue EML has the shortest light emission wavelength and the smallest value of the CBM among the blue EML, the green EML, and the red EML. Thus, when electrons easily move from the ETL to the blue EML, electrons also easily move from the ETL to the green EML and the red EML.

Accordingly, the number average particle diameter of the MOP is preferably equal to or less than 5 nm.

Note that the lower limit value of a particle diameter R2 of the MOP 141 is not particularly limited. However, when the particle diameter of the MOP 141 is less than 1 nm, a distribution of the particle diameters becomes too large as compared with the number average particle diameter, and the band gap sensitively changes with respect to a difference in particle diameter. For this reason, it is difficult to manufacture a plurality of MOPs 141 so that the dispersion of the band gap is sufficiently small. Thus, the particle diameter of the MOP 141 is preferably equal to or larger than 1 nm. Accordingly, the number average particle diameter of the MOP 141 is preferably equal to or more than 1 nm and equal to or less than 5 nm, for example.

In addition, as the number average particle diameter of the MOP decreases, a surface roughness of the ETL decreases. When the surface roughness of the ETL is small, it is possible to suppress the occurrence of film formation unevenness of a layer serving as an upper layer of the ETL and to form a layered type ETL having excellent electron transportability from the cathode electrode. When the ligand 142 is coordinated to the MOP 141, the distance g2 between the surfaces of the MOPs 141 adjacent to each other is increased, aggregation is suppressed, and the particle diameter is hardly increased. Thus, the above-described number average particle diameter can be obtained.

On the other hand, the number average value (number average particle diameter) of the particle diameter d1 (diameter) of the MOP 131 is preferably equal to or more than 5 nm and equal to or less than 10 nm.

As described above, when the number average particle diameter of the MOP becomes small, the CBM becomes shallow, the band gap becomes large, and the electron transport efficiency is improved. In addition, as the number average particle diameter of the MOP decreases, the surface roughness of the ETL decreases. However, in a case of MOPs that are dissolved in polar solvents, a distance between the surfaces of MOPs adjacent to each other is small, and the particle diameter tends to easily increase due to aggregation or the like. In particular, in a case of the MOP 131, no ligand is coordinated thereto, or the number of carbons of the coordinated ligand 132 is small and the carbon chain is short. Thus, the number average particle diameter of the MOP 131 tends to be approximately within the above range.

Further, in the present embodiment, when a number average value of a center-to-center distance L1 of the MOPs 131 adjacent to each other (average MOP center-to-center distance) is defined as L1_{ab} and the number average particle diameter of the MOP 131 is defined as d1_{ab}, L1_{ab} described above is preferably equal to or more than d1_{ab} and equal to or less than d1_{ab}+1 nm, as represented by the following Expression (1).

$$d {1}_{a b} \leq L {1}_{a b} \leq d {1}_{a b} + 1 nm \qquad ( 1 )$$

In other words, the distance g1 between the surfaces of the MOPs 141 adjacent to each other is preferably equal to or less than 1 nm (that is, equal to or more than 0 nm and equal to or less than 1 nm).

As a result of intensive studies by the inventors of the present application, the inventors of the present application have confirmed that the band gap in a thin film can be maintained in p-toluenethiol, for example, in which the number of carbons per molecule in the MOP 131 is 7, which is a maximum value. A molecular length of p-toluenethiol is approximately 0.5 nm, and at this time, L1_{ab} described above is L1_{ab}=d1_{ab}+2×the molecular length of p-toluenethiol (that is, a ligand length)=d1_{ab}+1 nm. Thus, the upper limit value of L1_{ab} described above is preferably d1_{ab}+1 nm as described above. Additionally, the lower limit value of L1_{ab} described above is the average MOP center-to-center distance of the MOPs 131 (equal to the number average particle diameter d1_{ab} of the MOPs 131) when the MOPs 131 adjacent to each other are in contact with each other when no ligand is coordinated thereto.

In addition, in the present embodiment, when the number average value of the center-to-center distance L2 of the MOPs 141 adjacent to each other (average MOP center-to-center distance) is denoted as L2_{ab}, and the number average particle diameter of the MOPs 141 is denoted as d2_{ab}, L2_{ab} described above is preferably more than d2_{ab}+1 nm described above and less than twice d2_{ab} described above as represented in the following Expression (2).

$$d {2}_{a b} + 1 nm < L {2}_{a b} < 2 \times d {2}_{a b} \qquad ( 2 )$$

In other words, the distance g2 between the surfaces of the MOPs 141 adjacent to each other is preferably more than 1 nm and less than the number average particle diameter of the MOP 141 (d2_{ab}).

As described above, the number of carbons per molecule in the ligand 142 is equal to or more than 8, and the lower limit value of L2_{ab} described above is larger than the upper limit value of L1_{ab} described above. Thus, L2_{ab} described above is preferably larger than d2_{ab}+1 nm described above.

In addition, when a density (filling rate) per unit volume of the MOP 141 in the second ETL 14 is less than 10 vol %, the density (filling rate) of the MOP 141 in the second ETL 14 is too low to transport electrons. Thus, the density per unit volume of the MOP 141 in the second ETL 14 is preferably equal to or more than 10 vol %. Accordingly, L2_{ab} described above is preferably smaller than L2_{ab} at which the density per unit volume of the MOP 141 in the second ETL 14 is 10 vol %. The value of L2_{ab} at which the density (filling rate) per unit volume of the MOP 141 in the second ETL 14 is 10 vol % is approximately 2×d2_{ab}. Thus, the upper limit value of L2_{ab} described above is preferably less than 2×d2_{ab}.

As described above, the average MOP center-to-center distance of the MOP 141 is larger than that of the MOP 131 due to the ligand 142 described above, and the number average particle diameter (d2_{ab}) is easily maintained to be small.

On the other hand, as described above, since no ligand is coordinated to the MOP 131 or the ligand 132 with the short chain including a smaller number of carbons per molecule than that of the ligand 142 is coordinated to the MOP 131, the MOP 131 has the average MOP center-to-center distance smaller than that of the MOP 141 and is dissolved in polar solvents.

Note that in the present embodiment, a density (filling rate) per unit volume of the MOP 141 in the second ETL 14 is given by the following Expression (3).

$$74 vol \% \times {( the number average diameter of the MOP 141 ( d {2}_{a b} ) / the average MOP center ‐ to ‐ center distance of the MOP 141 ( L {2}_{a b} ) )}^{3} \qquad ( 3 )$$

Note that 74 vol % is a filling rate of the MOPs in the ETL on the assumption that the MOPs are most tightly packed in the ETL when no ligand is coordinated to the MOPs (that is, when L2_{ab}=d2_{ab} is satisfied).

For example, when d2_{ab} is 5 nm, L2_{ab} satisfies 6 nm<L2_{ab}<10 nm from Expression (2) described above. Thus, when a density (filling rate) per unit volume of the MOP 141 in the second ETL 14 is denoted as F2, F2 described above in a case of d2_{ab}=5 nm satisfies 9.3 vol %<F2<43 vol %.

Further, as described above, when the density (F2) per unit volume of the MOP 141 in the second ETL 14 is less than 10 vol %, F2 described above is too low to transport electrons. Thus, F2 described above is preferably equal to or more than 10 vol %.

According to this, F2 described above is preferably equal to or more than 10 vol % and equal to or less than 74×(number average particle diameter (R2_{ab})/(number average particle diameter (R2_{ab})+1 nm))³ vol %.

Additionally, in the present embodiment, a density (filling rate) per unit volume of the MOP 131 in the first ETL 13 is given by the following Expression (4).

$$74 vol \% \times {( number average particle diameter of the MOP 131 ( d {1}_{a b} ) / average MOP center ‐ to ‐ center distance of the MOP 131 ( L {1}_{a b} ) )}^{3} \qquad ( 4 )$$

Further, as described above, the number average particle diameter of the MOP 131 (d1_{ab}) is equal to or less than the number average particle diameter of the MOP 141 (d2_{ab}), that is, (d1_{ab}<d2_{ab}) is satisfied. Assuming that the MOPs are most tightly packed in the ETL when no ligand is coordinated to the MOPs, the filling rate of the MOPs in the ETL is 74 vol %. Thus, when the density (filling rate) per unit volume of the MOPs 131 in the first ETL 13 is denoted as F1, F1 described above is preferably equal to or more than 74×(number average particle diameter (R2_{ab})/(number average particle diameter (R2_{ab})+1 nm))³ vol % and less than 74 vol %.

As described above, since no ligand is coordinated to the MOP 131 or the ligand 132 with the short chain including a smaller number of carbons per molecule than that of the ligand 142 is coordinated to the MOP 131, the MOP 131 has a higher density per unit volume than that of the MOP 141, and is dissolved in polar solvents as described above.

On the other hand, the MOP 141 has a lower density per unit volume than that of the MOP 131 due to the ligand 142, and is dissolved in non-polar solvents as described above.

Note that in the present embodiment, the polar solvent is preferably a solvent having a dielectric constant equal to or more than 4 and equal to or less than 100 as measured at around 20° C. to 25° C., and the non-polar solvent (apolar solvent) is preferably a solvent having the dielectric constant equal to or more than 1 and less than 4. Note that since the generally disclosed dielectric constant is a value measured at around 20° C. to 25° C., the generally disclosed dielectric constant can be employed as it is as the dielectric constant. Note that a measuring method and a measuring device for the dielectric constant are not particularly limited. As an example, a liquid dielectric constant meter can be used.

TABLE 2

| | Solvent | Relative dielectric constant |
|---|---|---|
| Non-polarity | Pentane | 1.8 |
| | Hexane | 1.9 |
| | Octane | 1.9 |
| | Cyclohexane | 2.0 |
| | Toluene | 2.4 |
| Polarity | Chloroform | 4.8 |
| | Butyl acetate | 5.0 |
| | Chlorobenzene | 5.6 |
| | Ethyl acetate | 6.0 |
| | Cyclohexanol | 15 |
| | 2-methoxyethanol | 17 |
| | 1-butanol | 18 |
| | 2-propanol | 20 |
| | Acetone | 21 |
| | Ethanol | 25 |
| | 2-ethoxyethanol | 30 |
| | Methanol | 33 |
| | Acetonitrile | 36 |
| | Ethylene glycol | 38 |
| | Dimethyl sulfoxide | 46 |
| | Water | 79 |

As shown in Table 2, examples of the solvent having the dielectric constant equal to or more than 1 and less than 4 include pentane, hexane, octane, cyclohexane, and toluene. As the non-polar solvent to be used in the present embodiment, for example, at least one type of organic solvent selected from the group consisting of the above-exemplified non-polar solvents is preferably used.

Additionally, as shown in Table 2, examples of the solvent having the dielectric constant equal to or more than 4 and equal to or less than 100 include chloroform, butyl acetate, chlorobenzene, ethyl acetate, cyclohexanol, 2-methoxyethanol, 1-butanol, 2-propanol, acetone, ethanol, 2-ethoxyethanol, methanol, acetonitrile, ethylene glycol, dimethyl sulfoxide, and water. As the polar solvent to be used in the present embodiment, for example, at least one solvent selected from the group consisting of the above-exemplified polar solvents is preferably used.

However, QDs to be dispersed in non-polar solvents are usually easily degraded in water. Thus, as the polar solvent to be used in a first material dispersion containing the MOPs 131 to be applied on the EML 12, for example, it is preferable to use at least one type of organic solvent selected from the group consisting of solvents other than water among the polar solvents esemplified above, that is, the polar organic solvents among the polar solvents exemplified in Table 2.

Note that in the present embodiment, a layer thickness of each layer other than the first ETL 13 and the second ETL 14 in the light-emitting element ES is not particularly limited, and can be set to a layer thickness similar to that in the related art.

In the present embodiment, an average layer thickness of the first ETL 13 is preferably equal to or more than 1 nm and equal to or less than 10 nm. As described above, the number average particle diameter (d1_{ab}) of the MOP 131 is preferably equal to or larger than 1 nm and equal to or less than 5 nm. At least one layer of the MOP 131 is formed in the first ETL 13. Thus, the lower limit of the average layer thickness of the first ETL 13 is preferably equal to or more than 1 nm. Note that the reason for the upper limit of the average layer thickness of the first ETL will be described later.

In addition, in the present embodiment, an average layer thickness of the second ETL 14 is preferably thicker than the average layer thickness of the first ETL 13. Note that the reason for this will be described below.

As described above, the number average particle diameter of the MOP 141 (d2_{ab}) is preferably equal to or larger than 5 nm and equal to or less than 10 nm. At least one layer of the MOP 141 is formed in the second ETL 14. Thus, the lower limit of the average layer thickness of the second ETL 14 is preferably equal to or more than 5 nm. Further, the average layer thickness of the second ETL 14 can be set in a manner similar to that of the average layer thickness of the known ETL. Thus, the upper limit of the average layer thickness of the second ETL 14 is preferably 100 nm, and the average layer thickness of the second ETL 14 is more preferably within a range more than 10 nm and equal to or less than 100 nm.

Additionally, as described above, the number average particle diameter of the MOP 131 (d1_{ab}) is equal to or less than the number average particle diameter of the MOP 141 (d2_{ab}), that is, (d1_{ab} d2_{ab}) is satisfied. Thus, the second ETL 14 has a lower surface roughness than that of the first ETL 13. For this reason, by layering the second ETL 14 on the first ETL 13, a small surface roughness thereof can be achieved, the occurrence of film formation unevenness of a layer serving as an upper layer thereof can be suppressed, and a layered type ETL having excellent electron transportability from the cathode electrode 25 can be formed.

According to the present embodiment, as described above, the surface roughness of the second ETL 14 can be made smaller than that of the first ETL 13, and preferably, the surface roughness of the second ETL 14 can be suppressed to be equal to or less than 3 nm.

Note that each of the surface roughness of the first ETL 13 and the surface roughness of the second ETL 14 is a surface roughness obtained by measuring a thin film formed by a spin coating method at a plurality of points (for example, about three points) with an Atomic Force Microscope (AFM) and averaging the measured values.

Manufacturing Method for Light-Emitting Element Next, an example of a manufacturing method for the light-emitting element ES according to the present embodiment will be described. Note that hereinafter, the manufacturing method for the light-emitting element ES in the light-emitting element layer 4 illustrated in FIG. 1 and having the structure illustrated in FIG. 2 will be described as an example of the manufacturing method for the light-emitting element ES.

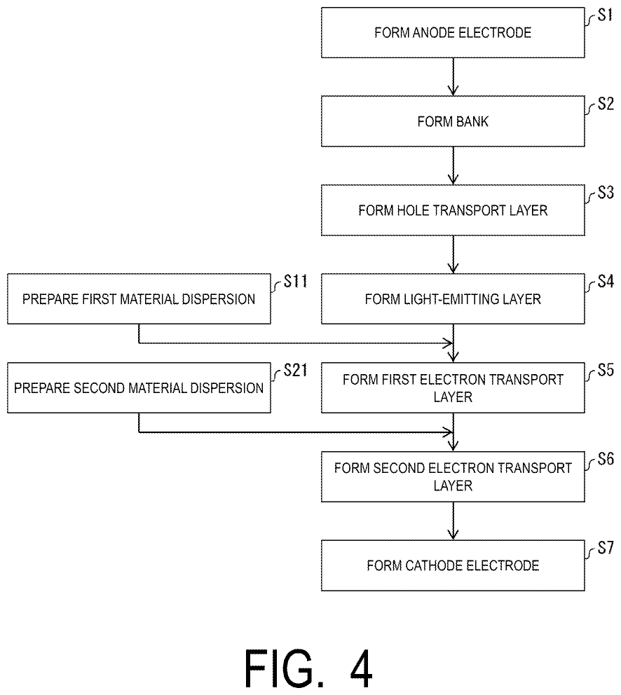

FIG. 4 is a flowchart illustrating an example of the manufacturing method for the light-emitting element ES according to the present embodiment.

As illustrated in FIG. 4, in order to manufacture the light-emitting element ES, first, the anode electrode 22 is formed on the substrate 3 serving as a support body (step S1, an anode electrode forming step). Next, a bank 23 is formed so as to cover the edge of the anode electrode 22 (step S2, a bank forming step). Subsequently, the HTL 11 is formed on the anode electrode 22 (step S3, a hole transport layer forming step). Then, the EML 12 is formed on the HTL 11 (step S4, a light-emitting layer forming step).

Separately, a first ETL material colloidal dispersion is prepared as a first material dispersion to be used for forming the first ETL 13 (step S11, a first material dispersion preparing step). The first ETL material colloidal dispersion contains at least the MOP 131 among the MOP 131 and the ligand 132, and a polar solvent. Thus, after the step S4 and the step S11, the first ETL material colloidal dispersion is applied onto the EML 12, and then, the polar solvent contained in the first ETL material colloidal dispersion is removed to dry the coating film. Due to this, the first ETL 13 is formed (step S5, a first electron transport layer forming step).

Separately, a second ETL material colloidal dispersion is prepared as a second material dispersion to be used for forming the second ETL 14 (step S21, a second material dispersion preparing step). The second ETL material colloidal dispersion contains the MOP 141, the ligand 142, and a non-polar solvent. Thus, after the step S5 and the step S21, the second ETL material colloidal dispersion is applied onto the first ETL 13, and then, the non-polar solvent contained in the second ETL material colloidal dispersion is removed to dry the coating film. Due to this, the second ETL 14 is formed (step S6, a second electron transport layer forming step). Subsequently, the cathode electrode 25 is formed on the second ETL 14 and the bank 23 (step S7, a cathode electrode forming step). In this way, the light-emitting element ES is formed.

For example, physical vapor deposition (PVD) such as a sputtering method or a vacuum vapor deposition technique, a spin coating method, an ink-jet method, or the like is used for formation of the anode electrode 22 in the step S1 and formation of the cathode electrode 25 in the step S7.

Further, in the step S2, the bank 23 can be formed into a desired shape by patterning a layer formed of an insulating material deposited by PVD such as a sputtering method or a vacuum vapor deposition technique, a spin coating method, a bar coating method, a spray method, an ink-jet method, or the like by using a photolithography method or the like.

In the step S3, when the HTL 11 is formed of an organic material, a vacuum vapor deposition technique, a spin coating method, an ink-jet method, or the like is appropriately used for film formation of the HTL 11. When the HTL 11 is made of an inorganic material, for example, PVD such as a sputtering method or a vacuum vapor deposition technique, a spin coating method, a bar coating method, a spray method, an ink-jet method, or the like is appropriately used for film formation of the HTL 11.

In the step S4, for the manufacture of the EML 12, as described above, a QD dispersion obtained by dispersing the QDs 121 in a non-polar solvent is used. The EML 12 can be formed by applying the QD dispersion onto an underlayer thereof (the HTL 11 in the present embodiment) and then, drying the coating film. For the application of the QD dispersion, for example, a spin coating method, a bar coating method, a spray method, an ink-jet method, or the like is used. Further, for drying the coating film, the non-polar solvent is removed by baking, for example. A drying temperature (baking temperature) is not particularly limited, but is preferably set to about a temperature at which the non-polar solvent can be removed in order to avoid thermal damage.

Note that when the display device 2 as a light-emitting device including the light-emitting elements ES is manufactured as described above, in the step S4, the blue EML is formed in the blue pixel PB, the green EML is formed in the green pixel PG, and the red EML is formed in the red pixel PR in a freely selected order.

In the step S5 and the step S6, the first ETL material colloidal dispersion and the second ETL material colloidal dispersion are applied by using, for example, a spin coating method, a bar coating method, a spray method, an ink-jet method, or the like as in the step S4. Additionally, for drying the coating film, for example, the solvent is removed by baking. A drying temperature (baking temperature) is not particularly limited, but is preferably set to about a temperature at which the solvent used for each ETL material colloidal dispersion can be removed in order to avoid thermal damage.

The preparation of the first ETL material colloidal dispersion in the step S11 and the liquid preparation of the second ETL material colloidal dispersion in the step S21 are carried out, for example, by the following method.

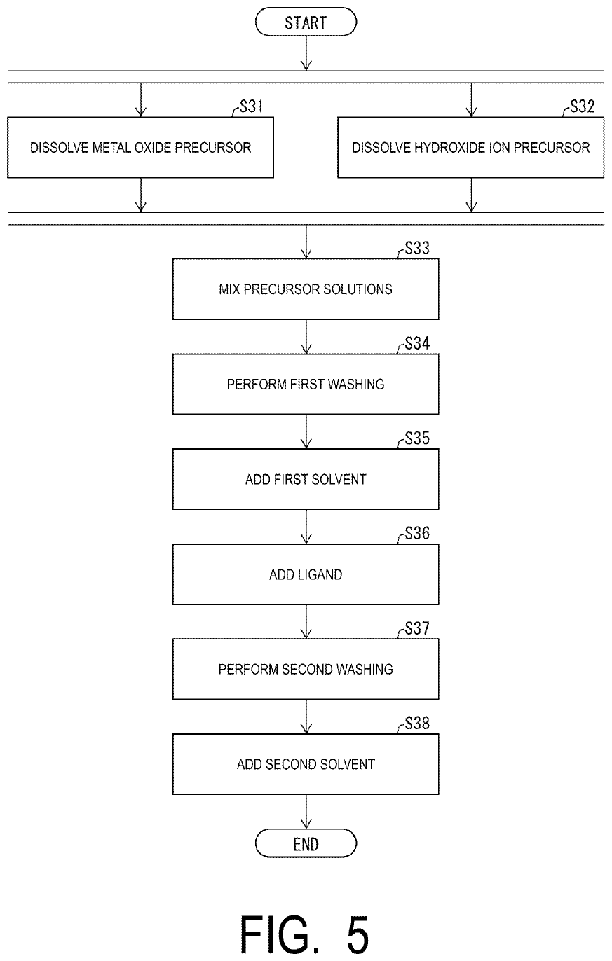

FIG. 5 is a flowchart illustrating an example of a method for preparing a colloidal dispersion (ETL material colloidal dispersion) to be used as the first ETL material colloidal dispersion (first material dispersion) or the second ETL material colloidal dispersion (second material dispersion).

In order to manufacture these ETL material colloidal dispersions, as illustrated in FIG. 5, a metal oxide precursor is dissolved in a solvent for dissolving the metal oxide precursor solvent to obtain a metal oxide precursor solution (step S31). The metal oxide precursor is a supply source of metal ions of the MOP contained in the ETL material colloidal dispersion. Thus, the metal oxide precursor preferably contains metal ions and anionized acid. Additionally, the anionized acid is preferably acetate ions or chloride ions. As an example, when the MOP contains ZnO, the metal oxide precursor may be zinc acetate. Note that the solvent for dissolving the metal oxide precursor is preferably a non-aqueous polar organic solvent such as dimethyl sulfoxide (DMSO) or an amphoteric polar organic solvent such as methanol or ethanol.

Separately, a hydroxide ion precursor is dissolved in a solvent for hydroxide ion precursor to obtain a hydroxide ion precursor solution (step S32). The hydroxide ion precursor is a supply source of hydroxide ions. Thus, the hydroxide ion precursor preferably contains a cationized base and a hydroxide ion. In addition, the cationized base preferably contains at least one type selected from the group consisting of a polyatomic ion represented by the following structural formula (A), a lithium ion, and a potassium ion. As an example, the hydroxide ion precursor may be tetramethylammonium hydroxide (TMAH). Note that the solvent for hydroxide ion precursor described above is preferably a non-aqueous polar organic solvent such as dimethyl sulfoxide (DMSO) or an amphoteric polar organic solvent such as methanol or ethanol.

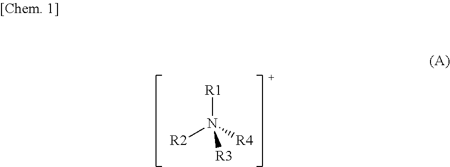

Note that in the above structural formula (A), R1 represents a methyl group or an ethyl group, and R2, R3, and R4 each independently represent a hydrogen atom, a methyl group, or an ethyl group.

After the step S31 and the step S32, subsequently, the metal oxide precursor solution and the hydroxide ion precursor solution are mixed to obtain a mixed solution. Then, the metal acid ions and the hydroxide ions are reacted with each other in the mixed solution to obtain metal hydroxide, and then, metal oxide is obtained by a following dehydration reaction. As an example, in a case where the metal oxide precursor is zinc acetate and the hydroxide ion precursor is TMAH, zinc hydroxide is generated by a reaction represented by the following reaction formula (B). Subsequently, zinc oxide nanoparticles are produced through a dehydration reaction represented by the following reaction formula (C).

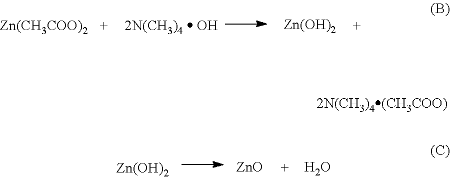

Then, the mixed solution is allowed to stand for a while to continue the two-stage reaction described above and grow the MOP. The longer the standing time is taken, the more the MOP grows and the larger a particle diameter thereof becomes. This MOP is used as the MOP 131 or the MOP 141. Thus, it is preferable to determine the standing time according to the particle diameter of the MOP to be used as the MOP 131 or the MOP 141 (step S33, a precursor solution mixing step (reacting step)).

Next, the reacted solution obtained by the above reaction is washed by using a poor solvent as a first rinse liquid to precipitate and separate (isolate) the MOP (step S34, a first washing step). As the poor solvent, for example, at least one type of solvent selected from the group consisting of acetone, ethyl acetate, butyl acetate, hexane, octane, toluene, and methanol is used. This washing may be performed once, but is preferably performed a plurality of times. As an example, a case where the metal oxide precursor is zinc acetate and the hydroxide ion precursor is TMAH will be described.

When an excessive amount of ethyl acetate is added to a solution, zinc oxide nanoparticles are not dispersed in ethyl acetate, and thus, form a precipitate. On the other hand, zinc acetate and TMAH are dissolved in ethyl acetate, and thus, do not form a precipitate. Thus, for example, by separating the precipitate and the solution by centrifugal separation and removing only the solution, zinc acetate and TMAH can be removed and only zinc oxide nanoparticles can be obtained. Note that the solvent may be removed together with zinc acetate and TMAH by heating or reducing an atmospheric pressure without being limited to the centrifugal separation.

By removing the unreacted metal ions and the hydroxide ion precursor from the mixed solution by the washing, the generation of the metal hydroxide is stopped, and then, the generation of the metal oxide is stopped. As a result, the increase in the particle diameter of the MOP due to the generation of the metal oxide stops. However, when the MOPs are dispersed in a solvent, an increase in the particle diameter of the MOP due to aggregation or Ostwald ripening of the MOPs continues to occur.

When a ligand is coordinated to the MOP, next, a first solvent is added as a dispersion medium to the precipitated MOP (step S35, a first solvent adding step), and then, a ligand is added to prepare a dispersion containing the MOP, the ligand, and the first solvent (step S36, a ligand adding step). This causes the ligand to coordinate to the MOP, which prevents aggregation and Ostwald ripening of the MOPs. Note that when the first ETL material colloidal dispersion is prepared as the ETL material colloidal dispersion and the ligand is not coordinated to the MOP, the process proceeds to step S38, which will be described below, after the step S34.

When the ligand is the ligand 132 and the first ETL material colloidal dispersion is prepared as the ETL material colloidal dispersion, a polar organic solvent is used as the first solvent. On the other hand, when the ligand is the ligand 142 and the second ETL material colloidal dispersion is prepared as the ETL material colloidal dispersion, a non-polar organic solvent is used as the first solvent.

Next, the dispersion containing the MOP, the ligand, and the first solvent is washed by using a second rinse liquid to precipitate and separate (isolate) the MOP to which the ligand is coordinated (step S37, a second washing step).

When the ligand is the ligand 132 and the first ETL material colloidal dispersion is prepared as the ETL material colloidal dispersion, a non-polar organic solvent is used as the second rinse liquid. On the other hand, when the ligand is the ligand 142 and the second ETL material colloidal dispersion is prepared as the ETL material colloidal dispersion, a polar organic solvent is used as the second rinse liquid.

The MOP to which the ligand 132 is coordinated is not dispersed in the non-polar organic solvent and becomes a precipitate. On the other hand, the ligand 132 itself is dissolved in the non-polar organic solvent. Further, the MOP to which the ligand 142 is coordinated is not dispersed in the polar organic solvent and becomes a precipitate. On the other hand, the ligand 142 itself is dissolved in the polar organic solvent. Thus, for example, by separating the precipitate and the solution by centrifugal separation and removing only the solution (liquid phase), it is possible to remove excessive ligands (unbound ligands) that are not coordinated to the MOPs. This washing may be performed once, but is preferably performed a plurality of times. Note that the method is not limited to the centrifugal separation, and the solvent may be removed together with the excessive ligands by heating or reducing an atmospheric pressure.

Thereafter, a second solvent as a dispersion medium is added to the precipitated MOPs to prepare the first ETL material colloidal dispersion as the first material dispersion or the second ETL material colloidal dispersion as the second material dispersion (step S38, a second solvent adding step).

When the ligand is the ligand 132 and the first ETL material colloidal dispersion is prepared as the ETL material colloidal dispersion, a polar organic solvent is used as the second solvent. On the other hand, when the ligand is the ligand 142 and the second ETL material colloidal dispersion is prepared as the ETL material colloidal dispersion, a non-polar organic solvent is used as the second solvent. Note that the second solvent added in the step S38 may be the same as or different from the first solvent added in the step S35.

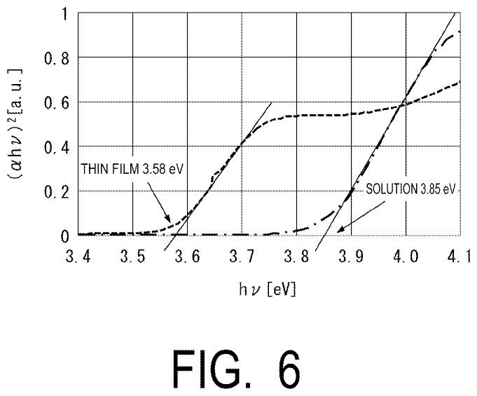

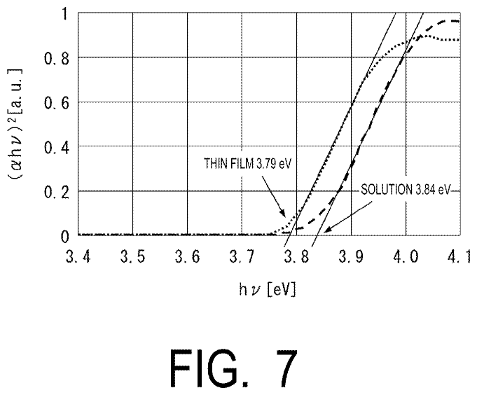

FIG. 6 is a graph illustrating a relationship between (αhv)² and hv in each of a solution state and a thin film state of zinc oxide nanoparticles (hereinafter, referred to as “ZnO nanoparticles”) to which no ligand is coordinated. FIG. 7 is a graph illustrating a relationship between (αhv)² and hv in each of a solution state and a thin film state of ZnO nanoparticles to which oleic acid is coordinated as the ligand with the long chain. Here, a represents a light absorption coefficient, and hv represents light energy (h=Planck's constant, v=frequency).

Note that the solution containing ZnO nanoparticles not coordinated with a ligand (ZnO nanoparticle colloidal dispersion) illustrated in FIG. 6 was prepared by the following method.

Specifically, in the step S31 illustrated in FIG. 5, zinc acetate as the metal oxide precursor was dissolved in DMSO at 60° C. and then, filtered to prepare a zinc acetate-DMSO solution having a concentration of 0.1 mol/L as the metal oxide precursor solution.

Further, in the step S32, TMAH as the hydroxide ion precursor was dissolved in methanol to prepare a TMAH-methanol solution having a concentration of 0.5 mol/L as the hydroxide ion precursor solution.

Next, in the step S33, 10 mL of the zinc acetate-DMSO solution (concentration: 0.1 mol/L) and 2 mL of the TMAH-methanol solution (concentration: 0.1 mol/L) were mixed and stood for 5 minutes at a room temperature (20° C.) to be allowed to react with each other, which forms ZnO nanoparticles as the MOPs.

Next, in the step S34, the reacted solution obtained by the above reaction was washed twice by using ethyl acetate as the first rinse liquid to precipitate the above ZnO nanoparticles. Thereafter, centrifugal separation was performed to remove only a liquid phase. Thus, the precipitated ZnO nanoparticles were isolated.

Next, in the step S38, 1 mL of 1-butanol was added as a dispersion medium to the precipitated ZnO nanoparticles. Thus, a solution containing ZnO nanoparticles not coordinated with a ligand (ZnO nanoparticle colloidal dispersion) illustrated in FIG. 6 was obtained.

In addition, in order to form a ZnO nanoparticle film (ZnO nanoparticles in a thin film state) to which no ligand was coordinated as illustrated in FIG. 6, the ZnO nanoparticle colloidal dispersion was applied onto a quartz substrate by a spin coating method and dried. Thus, a ZnO nanoparticle film having a thickness of 50 nm was formed.

Additionally, a solution containing ZnO nanoparticles coordinated with oleic acid as ligands (ligand-modified ZnO nanoparticle colloidal dispersion) illustrated in FIG. 7 was prepared by the following method.

Specifically, first, ZnO nanoparticles were formed by the same method as the method for forming the ZnO nanoparticles illustrated in FIG. 6. That is, in the process from the step S31 to the step S34 illustrated in FIG. 5, the ZnO nanoparticles were formed by performing the same reactions and operations as those in the step of forming the ZnO nanoparticles illustrated in FIG. 6. Next, in the step S35, 1 mL of hexane was added as the first solvent, and in the step S36, 300 μL of oleic acid was added as ligands. Thus, the oleic acid was coordinated to the ZnO nanoparticles. Next, in the step S37, a dispersion containing the ZnO nanoparticles, oleic acid and hexane was washed twice by using ethanol as the second rinse liquid to precipitate and isolate the ZnO nanoparticles coordinated with the oleic acid.

Next, in the step S38, 1 mL of hexane as a dispersion medium was added to the precipitated ZnO nanoparticles. As a result, a solution containing the ZnO nanoparticles coordinated with the oleic acid (ligand-modified ZnO nanoparticle colloidal dispersion) used in FIG. 7 was obtained.

In addition, in order to form a ZnO nanoparticle film (ligand-modified ZnO nanoparticles in a thin film state) to which the oleic acid was coordinated, which was used in FIG. 7, the above-described ligand-modified ZnO nanoparticle colloidal dispersion was applied onto a quartz substrate by a spin coating method and dried. Thus, a ligand-modified ZnO nanoparticle film having a thickness of 50 nm was formed.

A band gap of the ZnO nanoparticles in the ZnO nanoparticle colloidal dispersion can be calculated by measuring an optical absorption spectrum of the ZnO nanoparticle colloidal dispersion and performing a Tauc plot as illustrated in FIG. 6. Additionally, a band gap of the ZnO nanoparticles in a thin film state can be calculated by measuring an optical absorption spectrum of the ZnO nanoparticle film formed on the quartz substrate and performing a Tauc plot as illustrated in FIG. 6. Similarly, a band gap of the ligand-modified ZnO nanoparticles in the ligand-modified ZnO nanoparticle colloidal dispersion can be calculated by measuring an optical absorption spectrum of the ligand-modified ZnO nanoparticle colloidal dispersion and performing a Tauc plot as illustrated in FIG. 7. Further, a band gap of the ligand-modified ZnO nanoparticles in a thin film state can be calculated by measuring an optical absorption spectrum of the ligand-modified ZnO nanoparticle film formed on the quartz substrate and performing a Tauc plot as illustrated in FIG. 7. In the present embodiment, the Tauc plot was performed as illustrated in FIG. 6 and FIG. 7, and a point at which a tangent line of the graph illustrating the relationship between (αhv)² and hv crossed an hv axis was determined to be the band gap.

Further, the number average particle diameter of the ZnO nanoparticles in the ZnO nanoparticle colloidal dispersion, the number average particle diameter of the ZnO nanoparticles in the ligand-modified ZnO nanoparticle colloidal dispersion, the number average particle diameter of the ZnO nanoparticles in the ZnO nanoparticle film, and the ligand-modified ZnO nanoparticle film were measured by using cross-sectional TEM images as described above.

The number average particle diameter of the ZnO nanoparticles in the ZnO nanoparticle colloidal dispersion was 4.0 nm, and the number average particle diameter of the ZnO nanoparticles in the ZnO nanoparticle film was 5.6 nm. Further, as illustrated in FIG. 6, the band gap of the ZnO nanoparticles in the ZnO nanoparticle colloidal dispersion was 3.85 eV, and the band gap of the ZnO nanoparticles in the ZnO nanoparticle film was 3.58 eV.

As described above, since the MOPs to which no ligand was coordinated had a small average MOP center-to-center distance when the MOPs were changed from the solution state to the thin film state, the number average particle diameter increased when the MOPs were formed into a thin film, which made it difficult to maintain the band gap in the solution state. Note that as a result of intensive studies by the inventors of the present application, a similar tendency was obtained concerning an MOP to which a ligand with a short chain including from 1 to 7 carbons per molecule is coordinated.

On the other hand, the number average particle diameter of the ZnO nanoparticles in the ligand-modified ZnO nanoparticle colloidal dispersion was 4.0 nm, and the number average particle diameter of the ZnO nanoparticles in the ligand-modified ZnO nanoparticle film was 4.2 nm. Additionally, as illustrated in FIG. 7, the band gap of the ZnO nanoparticles in the ligand-modified ZnO nanoparticle colloidal dispersion was 3.84 eV, and the band gap of the ZnO nanoparticles in the ligand-modified ZnO nanoparticle film was 3.79 eV.

As described above, concerning the MOPs to which oleic acid with long chains was coordinated as the ligands, even when the MOPs were changed from the solution state to the thin film state, the MOPs have a large average MOP center-to-center distance, and when the MOPs were formed into a thin film, the number average particle diameter was hardly increased, and the band gap in the solution state was able to be substantially maintained. Note that as a result of intensive studies by the inventors of the present application, it was found that an MOP to which a ligand with a long chain including 8 or more carbons per molecule is coordinated is less likely to increase in number average particle diameter and can suppress a decrease in band gap in a solution state.

Thus, in the present embodiment, as described above, the anode electrode 22, the EML 12 containing the QD dispersed in non-polar solvents, the first ETL 13 containing the MOP 131 dispersed in polar solvents, the first ETL 13 being adjacent to the EML 12, the second ETL 14 containing the MOP 141 dispersed in non-polar solvents, the second ETL 14 being adjacent to the first ETL 13, and the cathode electrode 25 are layered in this order from the lower layer side. The light-emitting element ES according to the present embodiment has such a layered structure. As described above, the MOPs 131 that are dispersed in the polar solvent are, for example, the MOPs 131 to which no ligand is coordinated or the MOPs 131 to which the ligands 132 including from 1 to 7 carbons per molecule are coordinated. Further, the MOPs 141 that are dispersed in the non-polar solvent are, for example, the MOPs 141 to which the ligands 142 including from 8 to 30 carbons per molecule are coordinated.

According to the present embodiment, the MOPs 131 are dispersed in the polar solvent as described above, the first ETL 13 can be formed on the EML 12 so as to be adjacent to the EML 12 without using a non-polar solvent for dispersing the QDs contained in the EML 12. In addition, since the MOPs 141 are dispersed in the non-polar solvent, the second ETL 14 can be formed on the first ETL 13 so as to be adjacent to the first ETL 13 without using a polar solvent for dispersing the MOPs 131 contained in the first ETL 13. For this reason, according to the present embodiment, it is possible to form a layered type ETL using metal oxide having a large band gap and high electron transport efficiency on the EML 12 so as to be adjacent to the EML 12.

In addition, according to the present embodiment, when the first ETL 13 is formed, the QDs contained in the EML 12 are not dispersed in the solvent. Thus, there is no possibility that the EML 12 is collapsed and rendered unable to maintain the layer state, the layer thickness of the EML 12 is reduced (film loss), or the QDs are deteriorated by the solvent. In addition, when the second ETL 14 is formed, the MOPs 131 contained in the first ETL 13 are not dispersed in the solvent and the first ETL 13 is not dispersed in the solvent. Thus, there is no possibility that the first ETL 13 is collapsed and rendered unable to maintain the layer state, the layer thickness of the first ETL 13 is reduced (film loss), or the first ETL 13 is deteriorated by the solvent. This can suppress a change in band gap, maintain the band gap, and suppress deterioration of light-emission characteristics due to a solvent at the time of layering. Thus, according to the present embodiment, the light-emitting element ES having higher electron transport efficiency and more excellent light-emission characteristics than those of known light-emitting elements can be provided.

Note that whether a light-emitting element includes an ETL containing MOPs that are dispersed in polar solvents and an ETL containing MOPs that are dispersed in non-polar solvents can be checked by, for example, the following method.

First, an image of a cross section of the light-emitting element is captured with a TEM, and a cathode electrode is removed by laser cutting or the like. Next, an image of a cross section of the light-emitting element after the cathode electrode is removed is captured with a TEM to check whether the cathode electrode is removed and the ETL is exposed. Next, this light-emitting element is immersed in a non-polar solvent, and then, an image of the cross section of the light-emitting element is captured with a TEM to check whether the layer thickness of the ETL is reduced. When the ETL containing the MOPs that are dispersed in non-polar solvents is provided on a surface thereof, the MOPs that are dispersed in non-polar solvents are dispersed in the non-polar solvent, and the layer thickness of the ETL is reduced as the MOP is dispersed. On the other hand, when the ETL is not provided with the MOPs that are dispersed in non-polar solvents on the surface thereof, the ETL is not affected by the non-polar solvent, and the layer thickness of the ETL does not change before and after the light-emitting element is immersed in the non-polar solvent. Next, the light-emitting element is immersed in a polar solvent, and then, an image of the cross section of the light-emitting element is captured with a TEM to check whether the layer thickness of the ETL is reduced. When the ETL containing MOPs that are dispersed in polar solvents is provided on a surface thereof, the MOPs that are dispersed in polar solvents are dispersed in the polar solvent, and the layer thickness of the ETL is reduced as the MOP is dispersed. On the other hand, when the ETL is not provided with the MOPs that are dispersed in polar solvents on the surface thereof, the ETL is not affected by the polar solvent, and the layer thickness of the ETL does not change before and after the light-emitting element is immersed in the polar solvent.

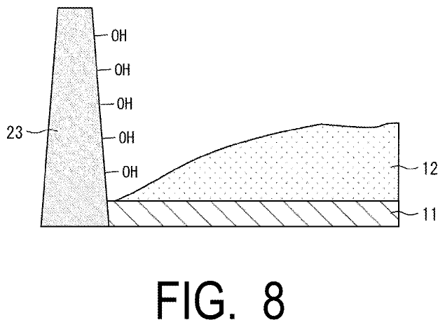

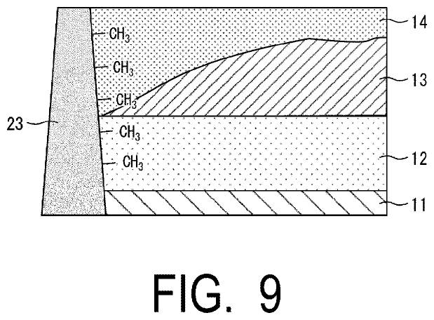

Note that FIG. 8 is a cross-sectional view illustrating an example of a schematic configuration of main portions when the bank 23 having good coatability with respect to polar solvents is used in the step S2 (bank forming step) illustrated in FIG. 4. FIG. 9 is a cross-sectional view illustrating an example of a schematic configuration of main portions when the bank 23 having good coatability with respect to non-polar solvents is used in the step S2 (bank forming step) illustrated in FIG. 4.

As illustrated in FIG. 8, when the bank 23 having good lyophilicity with respect to polar solvents is used as the bank 23, wettability of the QD dispersion with respect to the bank 23 is poor, and coatability of the QD dispersion thereto is lowered. As a result, the layer thickness of the EML 12 around the bank 23 is significantly reduced. Thus, in the present embodiment, as illustrated in FIG. 9, the bank 23 having good coatability with respect to non-polar solvents is used as the bank 23.

As described above, when the bank 23 having good lyophilicity with respect to non-polar solvents is used in order to improve the coatability of the QD dispersion, the wettability of the ZnO nanoparticle colloidal dispersion with respect to the bank 23 is poor, and the coatability of the ZnO nanoparticle colloidal dispersion is lowered. As a result, the layer thickness of the first ETL 13 around the bank 23 is significantly reduced.

However, according to the present embodiment, as described above, the second ETL 14 containing the MOPs 141 that are dispersed in non-polar solvents is layered on the first ETL 13. The ligand-modified ZnO nanoparticle colloidal dispersion has a small number average particle diameter of the MOPs 141 and has good wettability with respect to the bank 23. Thus, according to the present embodiment, when the bank 23 having good coatability with respect to the non-polar solvent is used, as illustrated in FIG. 2, FIG. 3, and FIG. 9, the QD dispersion can be uniformly applied and spread over the entire region surrounded by the bank 23. Further, as illustrated in FIG. 2, FIG. 3, and FIG. 9, a gap between the bank 23 and the first ETL 13 and recessed portions on a surface of the first ETL 13 can be filled with the second ETL 14. In addition, since the number average particle diameter of the MOPs 141 of the ligand-modified ZnO nanoparticle colloidal dispersion is small as described above, the second ETL 14 having a small surface roughness can be obtained. For this reason, according to the present embodiment, it is possible to obtain the light-emitting element ES that has high electron transport efficiency, that can improve luminous efficiency as compared with known light-emitting elements, and that has excellent uniform light emission properties.

Note that as described above, in the present embodiment, in order to uniformly apply a light-emitting material, the bank 23 having good lyophilicity with respect to non-polar solvents is formed. Thus, the first ETL 13 has low wettability and poor film formability with respect to the bank 23. Further, the metal oxide has a wide band gap and high electron transport efficiency. However, as described above, the first ETL 13 containing the MOPs 131 that are dispersed in polar solvents has a lower band gap and a higher surface roughness than those of the second ETL 14 containing the MOPs 141 that are dispersed in non-polar solvents. Then, as described above, forming the first ETL 13 allows the second ETL 14 to be formed. Thus, the first ETL 13 may be formed to such an extent that the second ETL 14 can be layered, and is desirably set to be equal to or less than 10 nm. Accordingly, the average layer thickness of the first ETL 13 is desirably set to be equal to or more than 1 nm and equal to or less than 10 nm as described above.

Note that the first ETL 13 has a large surface roughness, and the layer thickness of the first ETL 13 is discussed in terms of an average layer thickness that is an average of layer thicknesses thereof. The average layer thickness of the first ETL 13 is equal to a design value of the layer thickness of the first ETL 13, and can be translated into the design value of the layer thickness of the first ETL 13. Thus, the average layer thickness of the first ETL 13 indicates a median value of the layer thickness of the first ETL measured by a cross-sectional TEM or the design value of the layer thickness of the first ETL 13.

On the other hand, in the present embodiment, as described above, since the bank 23 having good lyophilicity with respect to non-polar solvents is formed, the second ETL 14 has high wettability and high film formability with respect to the bank 23.

Additionally, the second ETL 14 containing the MOPs 141 that are dispersed in non-polar solvents has a higher band gap and a smaller surface roughness than those of the first ETL 13 containing the MOPs 131 that are dispersed in polar solvents. Thus, the average layer thickness of the second ETL 14 is desirably thicker than the average layer thickness of the first ETL 13. Note that as described above, the second ETL 14 fills the gap between the bank 23 and the first ETL 13 and the recessed portions on the surface of the first ETL 13, thereby flattening the surface of the layered type ETL described above. Thus, in the present embodiment, similarly to the layer thickness of the first ETL 13, the layer thickness of the second ETL 14 is also discussed in terms of an average layer thickness that is an average of layer thicknesses thereof. The average layer thickness of the second ETL 14 is equal to a design value of the layer thickness of the second ETL 14, and can be translated into the design value of the layer thickness of the second ETL 14. Accordingly, the average layer thickness of the second ETL 14 indicates a median value of the layer thickness of the second ETL 14 measured by a cross-sectional TEM or the design value of the layer thickness of the second ETL 14.

### Modified Example

Note that the embodiments have been described based on, as an example, the case where the light-emitting device including the light-emitting elements ES is the display device. However, the present embodiment is not limited thereto, and the light-emitting device may be, for example, an illumination device.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
an anode electrode;
a light-emitting layer including a quantum dot dispersed in a non-polar solvent; and
a first electron transport layer including first metal oxide nanoparticles dispersed in a polar solvent, the first electron transport layer being adjacent to the light-emitting layer;
a second electron transport layer including second metal oxide nanoparticles dispersed in a non-polar solvent, the second electron transport layer being adjacent to the first electron transport layer; and
a cathode electrode,
wherein the anode electrode, the light-emitting layer, the first electron transport layer, the second electron transport layer, and the cathode electrode are layered in this order from a lower layer side.

2. The light-emitting element according to claim 1,
wherein the first electron transport layer does not include a ligand or includes a first ligand including from 1 to 7 carbons per molecule, and
the second electron transport layer includes a second ligand including from 8 to 30 carbons per molecule.

3. The light-emitting element according to claim 2,
wherein the first ligand is at least one type of ligand selected from the group consisting of ethanolamine, diethanolamine, triethanolamine, and p-toluenethiol.

4. The light-emitting element according to claim 2,
wherein the second ligand is at least one type of ligand selected from the group consisting of oleic acid, stearic acid, palmitic acid, octylphosphonic acid, tetradecylphosphonic acid, octadecylphosphonic acid, octylamine, dodecylamine, hexadecylamine, oleylamine, octanethiol, dodecanethiol, octadecanethiol, and trioctylphosphine.

5. The light-emitting element according to claim 2,
wherein a number average particle diameter of the second metal oxide nanoparticles is equal to or more than 1 nm and equal to or less than 5 nm.

6. The light-emitting element according to claim 2,
wherein a number average particle diameter of the first metal oxide nanoparticles is equal to or more than 5 nm and equal to or less than 10 nm.

7. The light-emitting element according to claim 2,
wherein a number average value of a center-to-center distance between second metal oxide nanoparticles adjacent to each other of the second metal oxide nanoparticles in the second electron transport layer is more than a number average particle diameter of the second metal oxide nanoparticles+1 nm and less than twice the number average particle diameter of the second metal oxide nanoparticles.

8. The light-emitting element according to claim 2,
wherein a number average value of a center-to-center distance between first metal oxide nanoparticles adjacent to each other of the first metal oxide nanoparticles in the first electron transport layer is equal to or more than a number average particle diameter of the first metal oxide nanoparticles and equal to or less than the number average particle diameter of the first metal oxide nanoparticles+1 nm.

9. The light-emitting element according to claim 2,
wherein a density per unit volume of the second metal oxide nanoparticles in the second electron transport layer is equal to or more than 10 vol % and equal to or less than 74×(a number average particle diameter/(the number average particle diameter+1 nm))³ vol %.

10. The light-emitting element according to claim 2,
wherein a density per unit volume of the first metal oxide nanoparticles in the first electron transport layer is equal to or more than 74×(a number average particle diameter/(the number average particle diameter+1 nm))³ vol % and less than 74 vol %.

11. The light-emitting element according to claim 1,
wherein an average layer thickness of the first electron transport layer is equal to or more than 1 nm and equal to or less than 10 nm.

12. The light-emitting element according to claim 1,
wherein an average layer thickness of the second electron transport layer is thicker than an average layer thickness of the first electron transport layer.

13. The light-emitting element according to claim 1,
wherein each of the first metal oxide nanoparticles and the second metal oxide nanoparticles includes zinc.

14. The light-emitting element according to claim 1,
wherein the non-polar solvent is a solvent having a dielectric constant equal to or more than 1 and less than 4.

15. The light-emitting element according to claim 1,
wherein the polar solvent is a solvent having a dielectric constant equal to or more than 4 and equal to or less than 100.

16. A light-emitting device comprising:
the light-emitting element according to claim 1.
